(19) United States
(12) Patent Application Publication
(10) Pub. No.: US 2011/0179992 A1
(43) Pub. Date: Jul. 28, 2011

(54) CRYSTAL GROWTH METHODS AND SYSTEMS

(76) Inventors: Carl Richard Schwerdtfeger, JR., Wilton, NH (US); Govindhan Dhanaraj, Merrimack, NH (US); Kedar Prasad Gupta, Hollis, NH (US)

(21) Appl. No.: 12/909,471

(22) Filed: Oct. 21, 2010

Related U.S. Application Data
(63) Continuation-in-part of application No. 12/588,656, filed on Oct. 22, 2009.
(60) Provisional application No. 61/108,213, filed on Oct. 24, 2008.
(60) Provisional application No. 61/379,358, filed on Sep. 1, 2010.

(51) Int. Cl. C30B 11/02

(52) U.S. Cl. 117/81

(57) ABSTRACT

Methods and systems related to an improved controlled heat extraction system for crystal growth, such as sapphire crystal growth are described, including methods and systems for mechanical probe-based and pyrometer-based inspection and automation processes, methods and systems for avoiding fusion of components, methods and systems for purging an inspection window, and methods and systems related to alternative crucible shapes.

### CROSS-REFERENCE TO RELATED APPLICATIONS

This application is a continuation-in-part of copending U.S. Nonprovisional patent application Ser. No. 12/588,656, Published Application No. US 2010-0101387, filed Oct. 22, 2009 entitled “CRYSTAL GROWING SYSTEM AND METHOD THEREOF,” the entirety of which is hereby incorporated herein by reference. U.S. Nonprovisional patent application Ser. No. 12/588,656 claims priority under 35 U.S.C. 119 to U.S. Provisional Application No. 61/108,213, filed Oct. 24, 2008, entitled “SYSTEM AND METHOD FOR GROWING CRYSTALS,” the entirety of which is hereby incorporated herein by reference. The present application also claims priority under 35 U.S.C. 119 to U.S. Provisional Application No. 61/379,358, filed Sep. 1, 2010, entitled “HIGH THROUGHPUT SAPPHIRE CORE PRODUCTION,” the entirety of which is hereby incorporated herein by reference.

### FIELD OF TECHNOLOGY

The present invention relates to a field of growing crystals and more particularly relates to methods and systems for growing large, highly pure crystals of, for example, sapphire.

### BACKGROUND

High brightness, low toxicity, low energy use, durability, small form factor, excellent color performance, and continuously decreasing costs, have led to a rapidly growing demand for light emitting diodes (LEDs) in a wide range of applications, such as small displays for mobile devices, flashes for digital cameras, backlighting units for displays used in computer monitors, liquid crystal display (LCD) televisions, public display signs, automotive lights, traffic signals, and general and specialty lighting for domestic and commercial premises.

Typically, LEDs are fabricated by growing several types of gallium nitride (GaN) crystalline active layers on a compatible substrate (also referred to as “wafer”). Further, the LEDs thus fabricated may have a mismatch between a crystal lattice of the compatible substrate and the GaN crystalline active layers. The mismatch is preferably small, so that a single crystal layer can be grown on a substrate. The substrate also preferably has high transparency, stability at temperatures up to 1100° C. or more, comparable thermal expansion and heat conduction with the grown GaN crystalline active layers. The physical properties of the preferred substrates (also referred to as “wafers”) are close to those of GaN and other layers, such as aluminum nitride (AIN), GaN, indium gallium nitride (InGaN) and indium gallium aluminum (InGaAl).

Even though there are several other potential substrate materials available, such as silicon carbide (SiC), silicon (Si), zinc oxide (ZnO) and GaN, sapphire (Al₂O₃) is a preferred substrate material for LEDs and other GaN device applications. Sapphire wafers of various diameters, typically two inches or larger in diameter, and various thicknesses, such as 150 or more micrometers (μm) are typically used for the fabrication of LEDs. In sapphire, the (0001) plane orientation has a relatively small mismatch with GaN when compared with other crystallographic orientations.

Currently, sapphire crystals are grown commercially by using one of the following techniques:

1) Czochralski method (Cz);

2) Kyropolous method (Ky);

3) Edge-defined Film Growth (EFG);

4) Bridgman (Br) method and variants of Br;

5) Heat Exchanger Method (HEM); and

6) Gradient Freeze (GF) and variants of GF.

However, the above methods have one or more shortcomings, such as: 1) presence of bubbles in the crystal, 2) defects and lattice distortion, 3) crucible design issues, 4) difficulty in measuring actual crystal growth rate, 5) limited size of crystals grown and 6) excessive cost due to an a-axis growth process. These shortcomings typically make yield low and cost of the wafer high. A need exists for improved crystal growth methods, including sapphire crystal growth methods.

### SUMMARY

A crystal growing system and method thereof is disclosed. According to one aspect of the present invention, a system for growing crystals from a molten charge material in a crucible may include a housing to form a chamber. The system may further include a seed cooling component, adapted to support a bottom of the crucible and to receive a coolant fluid to cool the supported portion of the crucible. The system may also include at least one heating element substantially surrounding the seed cooling component and the crucible to heat the crucible, where the seed cooling component along with the crucible is movable relative to the at least one heating element. Furthermore, the system may include an insulating element substantially surrounding the crucible, the seed cooling component and the at least one heating element.

Additionally, the system may include a gradient control device (GCD) movable relative to the insulating element, the at least one heating element, the seed cooling component and the crucible over a range of positions. The seed cooling component along with the crucible, the at least one heating element, the insulating element and the GCD may be enclosed in the housing.

The system may include a temperature control and a power control system to precisely control the temperature of the at least one heating element. Further, the system may include a motion controller to independently control the movement of the seed cooling component along with the crucible and the position of the GCD. Moreover, the system may include a vacuum pump to create and maintain a vacuum inside the housing during the crystal growth.

The method may include placing the seed crystal at the bottom of the crucible and placing the charge material in the crucible such that the seed crystal is substantially fully covered by the charge material. According to another aspect of the present invention, a method for growing a crystal may include heating a charge material along with a seed crystal in a crucible to slightly above a melting temperature of the charge material and maintaining the melt of the charge material for a pre-determined amount of time for homogenization. The method may also include substantially simultaneously cooling a bottom of the crucible to keep the seed crystal intact while the remainder of the charge material is in a molten state. Further, the method may include continually growing the crystal by substantially lowering the temperature of the melt and/or substantially lowering the crucible to maintain growth rate of the continually growing crystal to produce a substantially large crystal.

The method may also include extracting the larger crystal from the crucible upon completion of the crystal growth, coring the extracted larger crystal to produce a substantially cylindrical ingot, and slicing the cored cylindrical ingot to produce wafers.

According to yet another aspect of the present invention, a method is provided for growing a crystal in a controlled heat extraction system (CHES), having a housing, a seed cooling component adapted to support a bottom of a crucible and to receive a coolant fluid to cool the supported portion of the crucible, at least one heating element, an insulating element and a GCD. The method and system may include heating a charge material along with a seed crystal in a crucible to slightly above a melting temperature of the charge material using the at least one heating element. Further, the method may include maintaining the melt of the charge material for a pre-determined amount of time for homogenization using the at least one heating element. The method may also include substantially simultaneously cooling a bottom of the crucible to keep the seed crystal intact by flowing the coolant fluid through the seed cooling component.

Further, the method may include continually growing the crystal to produce a substantially large crystal. For continually growing the crystal, the cooling rate at the bottom of the crucible may be progressively increased by flowing the coolant fluid through the seed cooling component. The crucible may also be substantially lowered with respect to the at least one heating element using the seed cooling component 120 to maintain growth rate of the continually growing crystal to produce a larger crystal.

According to a further another aspect of the present invention, a system for growing crystals from a molten charge material in a crucible may include a housing to form a chamber. The system may also include a seed cooling component adapted to support a bottom of the crucible and to receive a coolant fluid to cool the supported portion of the crucible. The system may further include at least one heating element substantially surrounding the seed cooling component and the crucible. The at least one heating element may be adapted to heat the crucible. The at least one heating element may also be adapted to substantially slowly lower temperature inside the chamber during the crystal growth. The at least one heating element may be designed to cool the chamber at a rate approximately in the range of about 0.02 to 50 C/hr.

Additionally, the system may include an insulating element substantially surrounding the crucible, the seed cooling component and the at least one heating element. Moreover, the system may include a GCD movable relative to the insulating element, the at least one heating element, the seed cooling component and the crucible over a range of positions, and where the seed cooling component along with the crucible, the at least one heating element, the insulating element and the GCD are enclosed in the housing.

According to yet a further another aspect of the present invention, a system for growing crystals from a molten charge material in a crucible may include a housing to form a chamber. The system may also include a seed cooling component adapted to support a bottom of the crucible and to receive a coolant fluid to cool the supported portion of the crucible. The system may further include at least one heating element substantially surrounding the seed cooling component and the crucible.

The at least one heating element may be adapted to heat the crucible. The at least one heating element may also be adapted to substantially slowly lower temperature inside the chamber during the crystal growth. The at least one heating element may be designed to cool the heat zone at a rate approximately in the range of about 0.02 to 50 C/hr. The seed cooling component along with the crucible may be movable relative to the at least one heating element.

Additionally, the system may include an insulating element substantially surrounding the crucible, the seed cooling component and the at least one heating element. The system may also include a GCD movable relative to the insulating element, the at least one heating element, the seed cooling component and the crucible over a range of positions, and where the seed cooling component along with the crucible, the at least one heating element, the insulating element and the GCD are enclosed in the housing.

In certain optional preferred embodiments, methods and systems are provided for growing a sapphire crystal, such methods and systems optionally including using a pyrometer to observe a source material during heating of the source material; observing, based on a change in emissivity of the surface source material, a phase change in the source material; and using the observed phase change to determine an amount of heating required to induce the phase change. Such methods and systems may optionally include using a second pyrometer to obtain additional information about the source material and/or repeating a plurality of observations and using the observations to develop a heating algorithm that predicts heating time and amount required to melt a seed crystal. In certain optional embodiments, the first derivative of the temperature curve of the source material is used to determine the point of the phase change. Such methods and systems may optionally include deploying the pyrometer in proximity to a window of a sapphire crystal growth furnace to facilitate observation of sapphire crystal growth source material; deploying the pyrometer such that the window may be cleaned without moving the pyrometer; or deploying a calibration target item in the furnace to facilitate calibration of the pyrometer. In embodiments the sapphire crystal growth furnace is used in a c-axis sapphire crystal growth process. In certain optional embodiments the process is a controlled heat extraction process. Such methods and systems may optionally include controlling at least one of power and temperature in a controlled heat extraction sapphire crystal growth process based on readings from the pyrometer. In certain preferred embodiments the crystal growth process is a c-axis crystal growth process. In certain preferred embodiments the process is a controlled heat extraction process. In certain optional preferred embodiments, methods and systems are provided for growing a sapphire crystal, such methods and systems optionally including providing a window to facilitate observation of sapphire crystal growth in a sapphire crystal growth furnace; and providing a purging facility for reducing deposits on the sapphire growth window during sapphire crystal growth. In certain preferred embodiments, the purging facility flows a gas in proximity to an interior side of the window to diminish the flow of out-gassed particles toward the window. In certain embodiments the gas is an inert gas, such as argon gas. In embodiments the flow of argon gas creates a pressure curtain in proximity to the window. In certain preferred embodiments the methods and systems may include providing a facility for detecting discoloration of the window. In certain optional embodiments the discoloration detection facility includes a sensor for detecting at least one of an apparent color change of a target item in the furnace, an amount of deposition on the window, and state of cleanliness of the window. In certain preferred embodiments the sapphire crystal growth furnace is used in a c-axis sapphire crystal growth process. In certain preferred embodiments the process is a controlled heat extraction process.

In certain optional preferred embodiments, methods and systems are provided for growing a sapphire crystal, such methods and systems optionally including providing a probe for use in detecting the status of growth of a seed crystal in a sapphire crystal growth furnace; and deploying the probe in a sapphire crystal growth furnace to determine the size of a seed crystal. In certain preferred embodiments the probe is made at least in part of tungsten. In certain preferred embodiments the probe is disposed with a plurality of magnets to facilitate movement of the probe within the furnace. In certain preferred embodiments upon contact with the seed crystal, the probe stops moving relative to the movement of at least one moving magnet. In certain preferred embodiments the methods and systems may include a measuring facility for measuring the height of the seed crystal based on the position of the probe. In certain preferred embodiments the sapphire crystal growth furnace is used in a c-axis sapphire crystal growth process. In certain preferred embodiments the process is a controlled heat extraction process. In certain preferred embodiments the methods and systems may include automating a sapphire crystal growth process based on readings from the mechanical probe. In certain preferred embodiments the sapphire crystal growth furnace is used in a c-axis sapphire crystal growth process.

In certain optional preferred embodiments, methods and systems are provided for growing a sapphire crystal, such methods and systems optionally including providing a crucible for containing source material for sapphire crystal growth; providing a cooling shaft for cooling at least a zone of the crucible; and providing an intermediate facility for separating the crucible from the cooling shaft. In certain preferred embodiments at least one of the crucible and the cooling shaft is made at least in part of tungsten material. In certain preferred embodiments the intermediate facility is made of a material other than tungsten. In certain embodiments the intermediate facility is made of a heat-resistant alloy, such as molybdenum. In certain preferred embodiments the sapphire crystal growth crucible is used for c-axis sapphire crystal growth. In certain preferred embodiments the process is a controlled heat extraction process. In certain preferred embodiments the intermediate facility is a molybdenum disc. In certain preferred embodiments the intermediate facility is coated. In certain preferred embodiments the coating is a refractory oxide. In certain preferred embodiments the refractory oxide is selected from the group consisting of alumina, yttria, zirconia, and yttria stabilized zirconia.

In certain optional preferred embodiments, methods and systems are provided for growing a sapphire crystal, such methods and systems optionally including providing a crucible for sapphire crystal growth; and shaping the crucible in a non-circular shape, thereby facilitating growth of a crystal to a non-circular shape. In certain preferred embodiments the crucible is used in a c-axis sapphire crystal growth process. In certain preferred embodiments the process is a controlled heat extraction process. In certain preferred embodiments the crucible is formed by pressing and sintering, followed by machining to non-circular dimensions. In certain preferred embodiments the methods and systems may include positioning a seed crystal to facilitate a-axis growth that is orthogonal to a flat side of the crystal.

The methods and systems disclosed herein may be implemented in any means for achieving various aspects. Other features will be apparent from the accompanying drawings and from the detailed description that follow. All documents referred to herein are incorporated by reference in their entirety to the maximum extent allowed by applicable laws and regulations.

### BRIEF DESCRIPTION OF THE DRAWINGS

Various preferred embodiments are described herein with reference to the drawings, wherein:

FIG. 1A is a cross-sectional view of a furnace used in growing a single crystal about the c-axis, according to one embodiment;

FIG. 1B is a cross-sectional view of a furnace used in growing a single crystal about the c-axis, according to another embodiment;

FIG. 1C is a cross-sectional view of a furnace used in growing a single crystal about the c-axis, according to yet another embodiment;

FIGS. 2 through 4 illustrate a process of formation of a cored c-axis cylindrical ingot from a seed crystal, according to one embodiment;

FIG. 5 is a process flowchart of an exemplary method of certain steps for growing a single crystal about the c-axis using the furnace, such as those shown in FIG. 1A, and thereafter producing wafers using the single crystal, according to one embodiment; and

FIG. 6 is a schematic diagram illustrating a controlled heat extraction system (CHES) with the furnace, such as those shown in FIG. 1A, used in growing the single crystal along the c-axis, according to one embodiment.

FIG. 7 is a schematic diagram showing a probe for determining the status of a seed crystal in a crystal growth method.

FIG. 7A shows the probe of FIG. 7 during measurement.

FIG. 8 is a schematic diagram showing a set of views of a pyrometer for automating elements of power and temperature control in a crystal growth method.

FIG. 9 shows a pattern of temperature change of material in a crystal growth heating furnace during a phase change from solid to liquid.

FIG. 10 shows a window purging design for an observation window for a crystal growth furnace.

FIG. 11 illustrates an insulating layer between a seed cooling shaft and a crucible of a crystal growth system.

FIG. 12 illustrates an alternative crucible shape for a crystal growth system.

FIG. 13 illustrates material saved by using non-circular crucible shapes.

FIG. 14 is a logical diagram illustrating certain input elements, system elements, and applications related to crystal growth methods as described herein.

The drawings described herein are for illustration purposes only and are not intended to limit the scope of the present disclosure in any way.

### DETAILED DESCRIPTION

A crystal growing system and method thereof is disclosed. In the following detailed description of the embodiments of the invention, reference is made to the accompanying drawings that form a part hereof, and in which are shown, by way of illustration, specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined by the appended claims.

The terms ‘larger solidified single crystal’, ‘larger single crystal’, ‘larger crystal’ and ‘single crystal’ are used interchangeably throughout the document. Also, the terms ‘convex crystal growing surface’ and ‘crystal growing surface’ are used interchangeably throughout the document. Further, the term ‘about an axis’ refers to growing a single crystal approximately −150 to +150 from the axis, where the axis may be one of c-axis, a-axis, m-axis or r-axis.

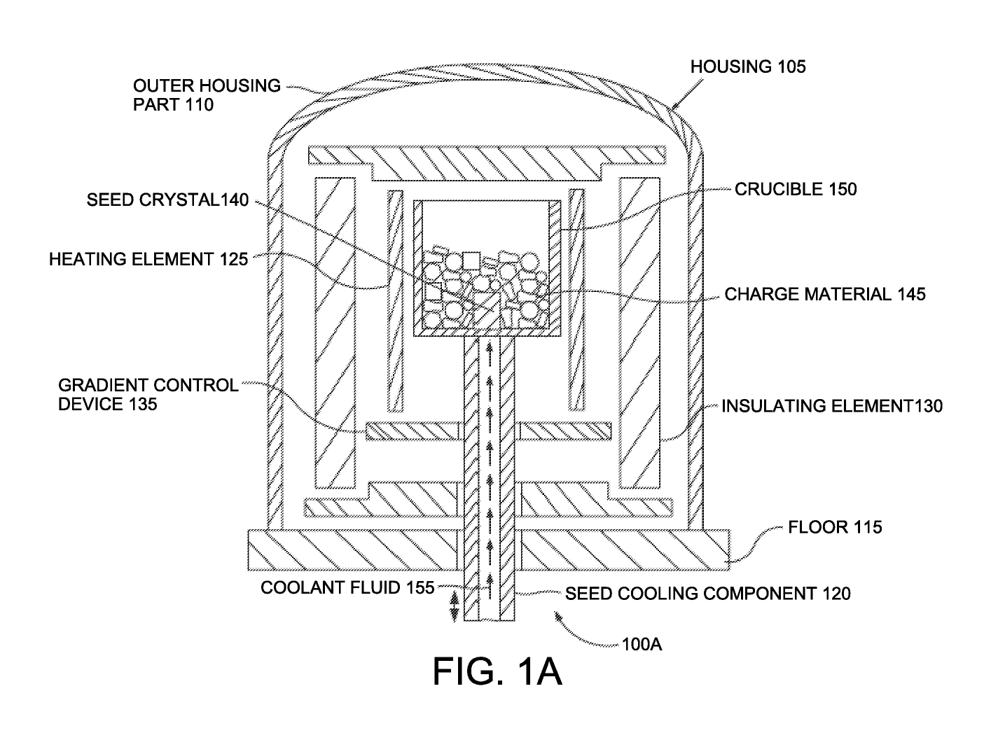

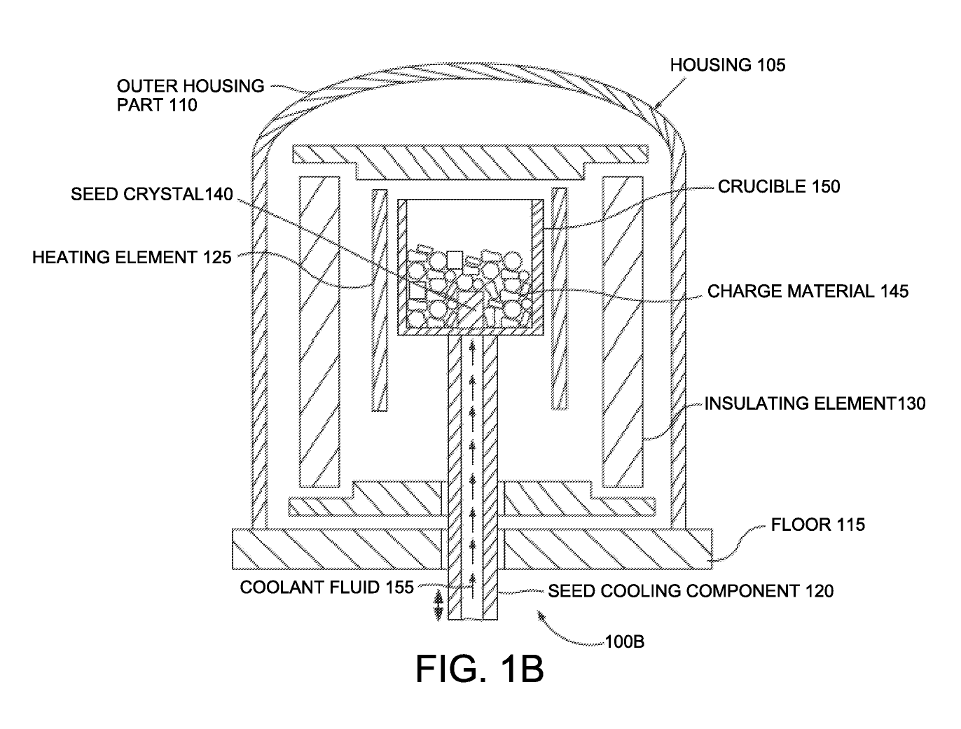

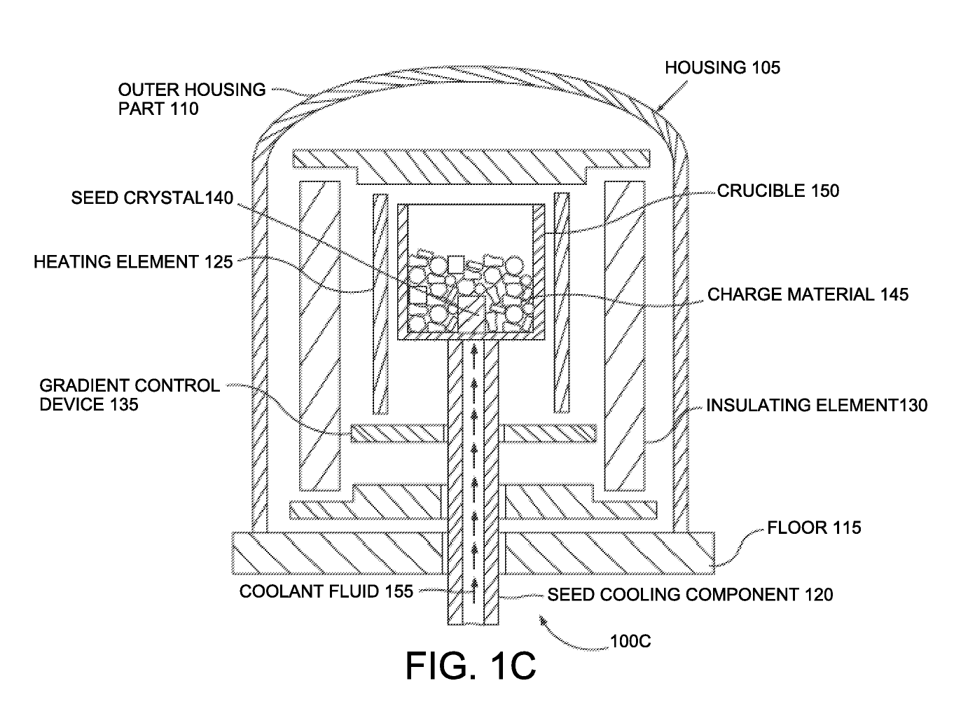

FIG. 1A is a cross-sectional view of a furnace 100A used in growing a single crystal about the c-axis, according to one embodiment. In FIG. 1A, the furnace 100A may include a housing 105. The housing 105 may include an outer housing part 110 and a floor 115. The outer housing part 110 and the floor 115 together form a chamber, which in certain embodiments may be a double walled, water cooled chamber, the interior portion of which may include a zone for heating and cooling material. References throughout this application to the heat zone, the melt, the furnace and the chamber may, where context indicates, refer to this interior portion of the chamber. The furnace 100A also may include a seed cooling component 120, a heating element(s) 125, an insulating element 130, a gradient control device (GCD) 135 and a crucible 150, all of which are enclosed in the outer housing part 110.

The crucible 150 may be a container holding a seed crystal 140 (e.g., D shaped, circular shaped, etc.) and a charge material 145 (e.g., sapphire (Al₂O₃), silicon (Si), calcium fluoride (CaF₂), sodium iodide (NaI), and other halide group salt crystals). As illustrated, the crucible 150 sits on the seed cooling component 120. The seed cooling component 120 may be a hollow component (e.g., made of a refractory metal such as tungsten (W), molybdenum (Mo), niobium (Nb), lanthanum (La), tantalum (Ta), rhenium (Re) or their alloys) that supports a bottom of the crucible 150. The seed cooling component 120 also receives a coolant fluid 155 (e.g., helium (He), neon (Ne) and hydrogen (H)) to cool the supported portion of the crucible 150 through the hollow portion.

The heating element(s) 125 substantially surrounds the seed cooling component 120 and the crucible 150. In one embodiment, the heating element(s) 125 is adapted to heat the crucible 150. In another embodiment, the heating element(s) 125 is adapted to substantially slowly lower temperature inside the heat zone of the chamber during crystal growth. For example, the heating element(s) 125 is designed to cool the heat zone at a rate approximately in the range of about 0.02 to 50 C/hr.

In some embodiments, the seed cooling component 120 along with the crucible 150 is movable relative to the heating element(s) 125. In these embodiments, the seed cooling component 120 is moved through one or more openings in the floor 115 of the housing 105. The insulating element 130 substantially surrounds the seed cooling component 120, the heating element(s) 125 and the crucible 150 and prevents heat transfer from the furnace 100A. For example, the insulating element 130 may be made of material such as W, Mo, graphite (C), and high temperature ceramic materials. The GCD 135 may be movable relative to the seed cooling component 120, the heating element(s) 125, the insulating element 130 and the crucible 150 over a range of positions.

In operation, the charge material 145 along with the seed crystal 140 in the crucible 150 heated to substantially slightly above a melting temperature of the charge material 145 using the heating element(s) 125. For example, the charge material 145 is heated to a temperature approximately in the range of about 2040° C. to 2100° C. Once the charge material 145 is completely molten, the molten charge material (also referred to as melt of the charge material) is maintained for a pre-determined amount of time (e.g., 1 to 24 hours) for homogenization.

Simultaneously to the heating of the charge material 145, the bottom of the crucible 150 is cooled by flowing the coolant fluid 155 (e.g., at a rate of 10 to 100 liters per minute (lpm)) through the seed cooling component 120. The bottom of the crucible 150 is cooled such that the seed crystal 140 remains intact and not melted completely. After soaking the melt for homogenization, the growth of the crystal is initiated along the c-axis.

In one or more embodiments, as the crystal grows, the cooling rate at the bottom of the crucible 150 is increased progressively by ramping up the flow rate of the coolant fluid 155 (e.g., up to 600 lpm over a period of 24 to 96 hours) through the seed cooling component 120. Concurrently, the temperature of the melt is substantially lowered at a rate of 0.02 to 50 C/hr by substantially slowly lowering the temperature of the heating element(s) 125. As a result, the melt is under-cooled as well as a temperature gradient is generated between the growing crystal and the melt. The process of under-cooling the melt and generation of the temperature gradient between the growing crystal and the melt by substantially slowly lowering the temperature of the heating element(s) 125 is known as gradient freeze (GF).

Further, as the crystal grows taller, the effect of the coolant fluid 155 reduces and hence the growth rate of the crystal slows down steadily. To compensate for the reduced growth rate of the crystal, the crucible 150 is lowered substantially at a rate of 0.1 to 5 mm/hr by moving the seed cooling component 120. Also, the temperature gradient is substantially varied to ensure a continued growth of the crystal and to produce a larger solidified single crystal. The temperature gradient is varied by moving the GCD 135 at a rate of 0.1 to 5 mm/hr. In these embodiments, the larger solidified single crystal (e.g., weighing from 0.3 to 450 Kilograms) is grown in the furnace 100A about a high yield c-axis.

On completion of the crystal growth, temperature of the furnace 100A is reduced below the melting temperature of the charge material 145 to cool the larger solidified single crystal to a room temperature. This is achieved by lowering the temperature of the heating element(s) 125, reducing the flow of the coolant fluid 155 to stop removal of heat from the bottom of the crucible 150, and moving the GCD 135 to a favorable position to reduce the temperature gradient. Further, inert gas pressure inside the furnace 100A is increased before the larger solidified single crystal is extracted from the furnace 100A. One can envision that, larger single crystals can also be grown about a-axis, r-axis or m-axis using the above described furnace 100A.

FIG. 1B is a cross-sectional view of a furnace 100B used in growing a single crystal about the c-axis, according to another embodiment. The furnace 100B of FIG. 1B is similar to the furnace 100A of FIG. 1A, except the furnace 100B does not include a GCD and also the heating element(s) 125 is not designed to substantially lower the temperature of the heat zone.

FIG. 1C is a cross-sectional view of a furnace 100C used in growing a single crystal about the c-axis, according to another embodiment. The furnace 100C of FIG. 1C is similar to the furnace 100A of FIG. 1A, except in the furnace 100C, the seed cooling component 120 is fixed such that the seed cooling component along with the crucible 150 is immovable with respect to the heating element(s) 125.

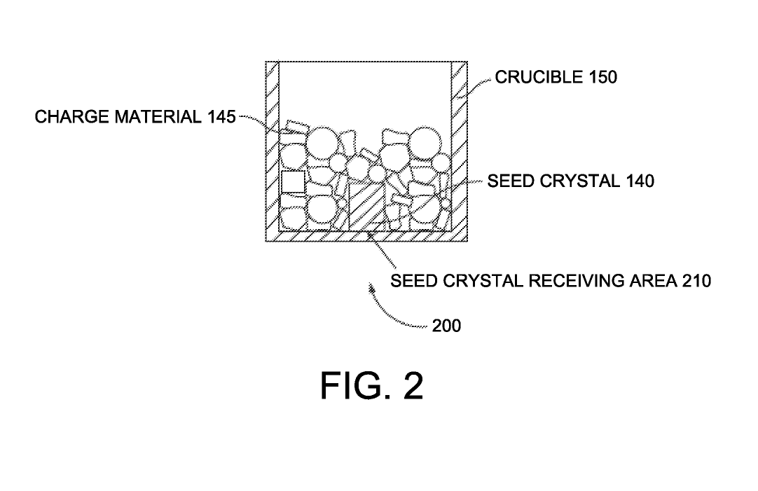

FIGS. 2 through 4 illustrate a process of formation of a cored c-axis cylindrical ingot 440 from the seed crystal 140, according to one embodiment. In one example embodiment, the cored c-axis cylindrical ingot 440 may be a sapphire ingot. In particular, FIG. 2 shows the crucible 150 having the seed crystal 140 along with the charge material 145. The crucible 150 may be made of a metallic material (e.g., Mo, W, or alloys of Mo and W) or a non-metallic material (e.g., graphite (C), boron nitride (BN), and the like). Further, the crucible 150 is capable of holding 0.3 to 450 Kilograms of the charge material 145.

The crucible 150 may include a seed crystal receiving area 210. The seed crystal receiving area 210 holds the seed crystal 140 in the crucible 150. In one embodiment, the seed crystal receiving area 210 allows a seed crystal of predetermined shape or size to be oriented in only one way or in any way in the seed crystal receiving area 210. The phrase ‘oriented in only one way’ refers to positioning of a D shaped seed crystal in only one position in the seed crystal receiving area 210, whereas the phrase ‘oriented in any way’ refers to positioning of a circular shaped seed crystal in any position within 360° in the seed crystal receiving area 210. It can be noted that the orientation of the seed crystal 140 in the seed crystal receiving area 210 may control orientation of the growing crystal about the c-axis. As illustrated in FIG. 2, the charge material 145 is placed in the crucible 150 in such a way that the seed crystal 140 is substantially fully covered by the charge material 145.

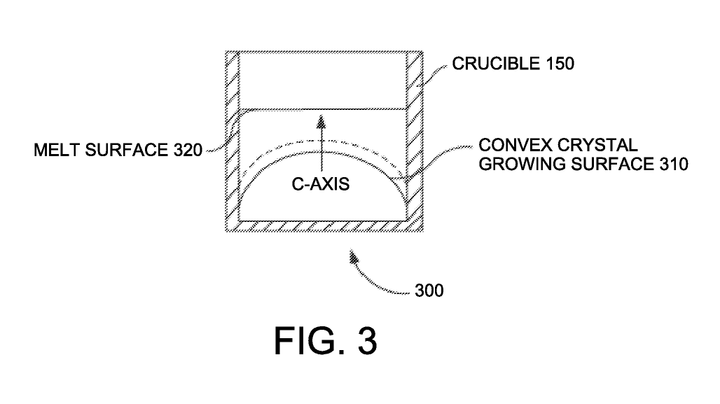

In an exemplary process, the crucible 150 with the charge material 145 and the seed crystal 140 is placed in the furnace (e.g., the furnace 100A, the furnace 100B or furnace 100C) for growing a larger single crystal about the c-axis. The charge material 145 then is heated above the melting temperature of the charge material 145. Further, the melt is maintained for the pre-determined amount of time for homogenization, to initiate the crystal growth about the c-axis. Concurrently, the bottom of the crucible 150 is cooled by flowing helium through the seed cooling component 120 to keep the seed crystal 140 intact. Accordingly, the seed crystal 140 starts growing about the c-axis along a crystal growing surface, as illustrated in FIG. 3.

In one embodiment, the crystal growing surface is formed starting from melting a small portion of a top surface (e.g., c-face) of the seed crystal 140. The small portion of the top surface of the seed crystal 140 is melted by increasing the temperature of the melt and/or reducing the flow rate of helium (e.g., from 90 lpm to 80 lpm) through the seed cooling component 120, resulting in a convex (or dome) shaped crystal growing surface 310. The convex crystal growing surface 310 may include micro steps made of a-plane and c plane and is maintained during the crystal growth. The convex crystal growing surface 310 assists substantially to increase the growth rate of the crystal about the c-axis.

For continually growing the crystal along the convex crystal growing surface 310, the cooling rate at the bottom of the crucible 150 is increased and the temperature of the melt is lowered. Further, the crucible 150 is lowered with respect to the heating element(s) 125 to compensate for the sluggish growth rate of the crystal (as the effect of the coolant fluid 155 is reduced). Also, the GCD 135 is moved such that the temperature gradient is varied. The above-mentioned process enables the crystal to grow continually along the c-axis resulting in a larger single crystal. As illustrated in FIG. 3, the crystal grows inside the melt predominantly along the c-direction.

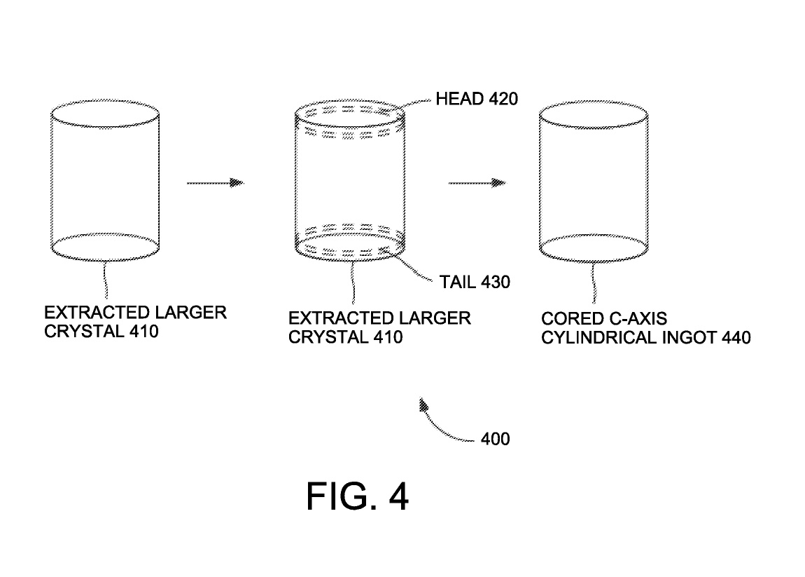

On completion of the crystal growth, the larger single crystal is extracted from the crucible 150. The extracted larger crystal 410 is then cored. As illustrated in FIG. 4, a top surface (e.g., a head 420 and a tail 430) of the extracted larger crystal 410 is cored. Thus, the cored c-axis cylindrical ingot 440 is obtained (e.g., with minimum grinding). Finally, the cored c-axis cylindrical ingot 440 is sliced to produce wafers that are used in optics and semiconductor applications.

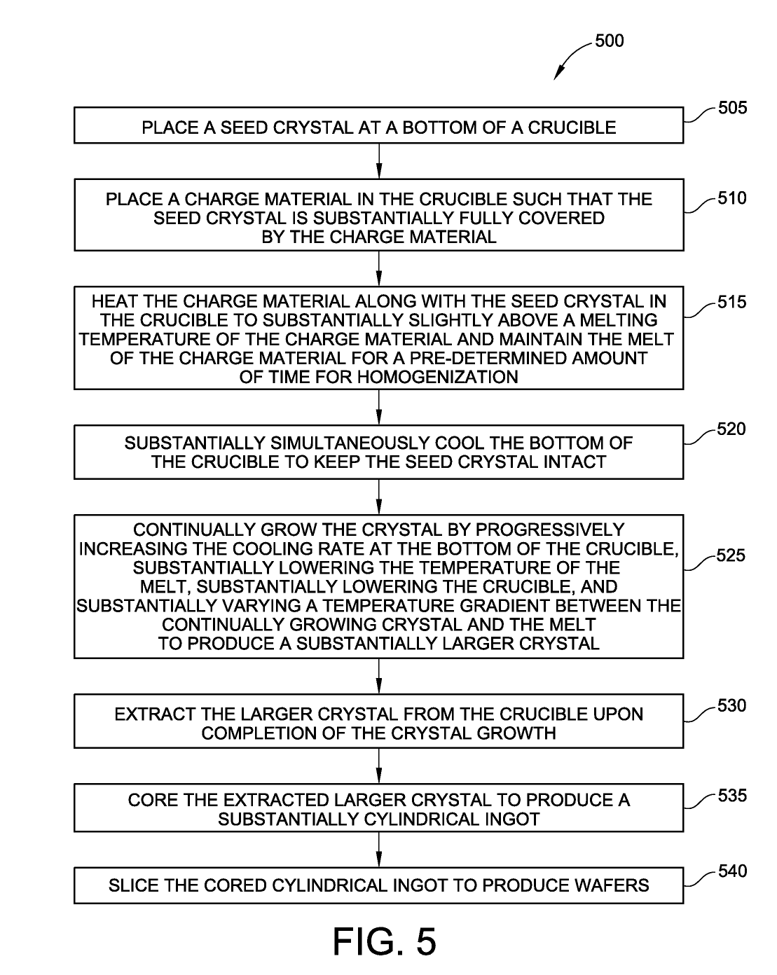

FIG. 5 is a process flowchart 500 of an exemplary method of growing a single crystal about the c-axis using the furnace 100A, such as those shown in FIG. 1A, and thereafter producing wafers using the single crystal, according to one embodiment. In step 505, a seed crystal (e.g., sapphire seed crystal) is placed at a bottom of the crucible 150. In step 510, a charge material (e.g., a sapphire charge material) is placed in the crucible 150 such that the seed crystal is substantially fully covered by the charge material. Then, the crucible 150 with the charge material and the seed crystal is loaded into the furnace 100A.

In step 515, the charge material along with the seed crystal in the crucible 150 is heated (e.g., using the heating element(s) 125) to substantially slightly above the melting temperature (e.g., in the range of about 2040° C. to 2100° C.) of the charge material. Then, the melt of the charge material is maintained above the melting temperature for a pre-determined amount of time (e.g., 1 to 24 hours). In one example embodiment, the melt of the charge material is maintained above the melting temperature for homogenization.

Further, in step 520, the bottom of the crucible 150 is cooled (e.g., simultaneously to the heating process in step 515) to keep the seed crystal intact with minimal desired melting. In case of the seed crystal oriented along the c-axis, the minimal desired melting may include melting a portion of a top surface (e.g., c-face) of the seed crystal to form a convex crystal growing surface, as shown in FIG. 3. The convex crystal growing surface is a true non-habit face (e.g., not the true c-face) having multi-steps made of a-plane and c-plane. The convex crystal growing surface helps safely increase a growth rate of the crystal about the c-axis.

In one embodiment, the bottom of the crucible 150 is cooled using helium when the melt of the charge material is above the melting temperature. For example, the helium is flown through the seed cooling component 120 supporting the bottom of the crucible 150 at a rate approximately in the range of about 10 to 100 lpm. In step 525, a crystal is continually grown about the c-axis to produce a larger crystal. During the crystal growth, the cooling rate at the bottom of the crucible 150 is increased substantially by increasing the flow rate of helium (e.g., up to 600 lpm over a period of 24 to 96 hours). Also, the temperature of the melt is lowered by substantially slowly lowering the temperature of the heating element(s) 125 at a rate of about 0.02 to 50 C/hr. As a result, a temperature gradient is generated between the continually growing crystal and the melt. Further, as the crystal grows taller, the crucible 150 is lowered with respect to the heating element(s) 125 using the seed cooling component 120 at a rate of about 0.1 to 5 mm/hr. The crucible 150 is lowered to maintain the growth rate of the continually growing crystal. Also, the temperature gradient is substantially varied by moving the GCD 135 to ensure continued growth of the crystal to produce the larger crystal.

In step 530, the larger crystal is extracted from the crucible 150 upon completion of the crystal growth. In step 535, the extracted larger crystal is cored to produce a substantially cylindrical ingot. In one embodiment, the cylindrical ingot is produced by coring substantially perpendicular to the top surface of the extracted larger crystal, as shown in FIG. 4. In step 540, the cored cylindrical ingot is sliced to produce wafers. It should be noted that while FIG. 5 depicts steps in an exemplary method, in alternative embodiments that would be understood by one of ordinary skill in the art, certain steps may be altered or omitted, the order of steps may be adjusted, or additional steps may included. Such additional steps may include evacuating the chamber, backfilling the chamber with a gas, such as argon, and the like.

Controlled Heat Extraction System (CHES) is a directional solidification process, which, in the various embodiments disclosed herein, may be used for growth of crystals, such as sapphire (single crystal form of aluminum oxide) boules. Sapphire's attractive mechanical, thermal and optical properties have been used for high performance, high temperature, robust, abrasion resistant, large windows for civilian and military applications. Recently sapphire substrates have become the substrate choice for blue light emitting diodes (LED), which has attractive potential for widespread use in low cost, reliable, durable, high performance lighting applications. While this disclosure is primarily directed towards sapphire and LED applications using CHES approach, to one skilled in the art, certain elements of it can be applied to other materials, different applications and for other processes.

As described in part throughout other portions of this disclosure, in a single crystal growth conversion process the charge material 145 (typically of the same chemical composition as the final crystal) is melted, and the temperature of the melt is raised above the melting point of the material. The melt is then “seeded” which involves melt being in contact with a single crystal ‘seed crystal’. The seed crystal 140 is partially melted back so it is wetted by the melt. Thereafter, conditions are created such that controlled growth is achieved off the melted back seed crystal 140 such that single crystal growth is promoted and maintained till all the molten material is solidified. After complete growth is achieved the material is just below its melting point, so it has to be cooled again at a controlled rate so that defect formation is minimized and cracking is eliminated. In case of sapphire the melting point is 2040° C.

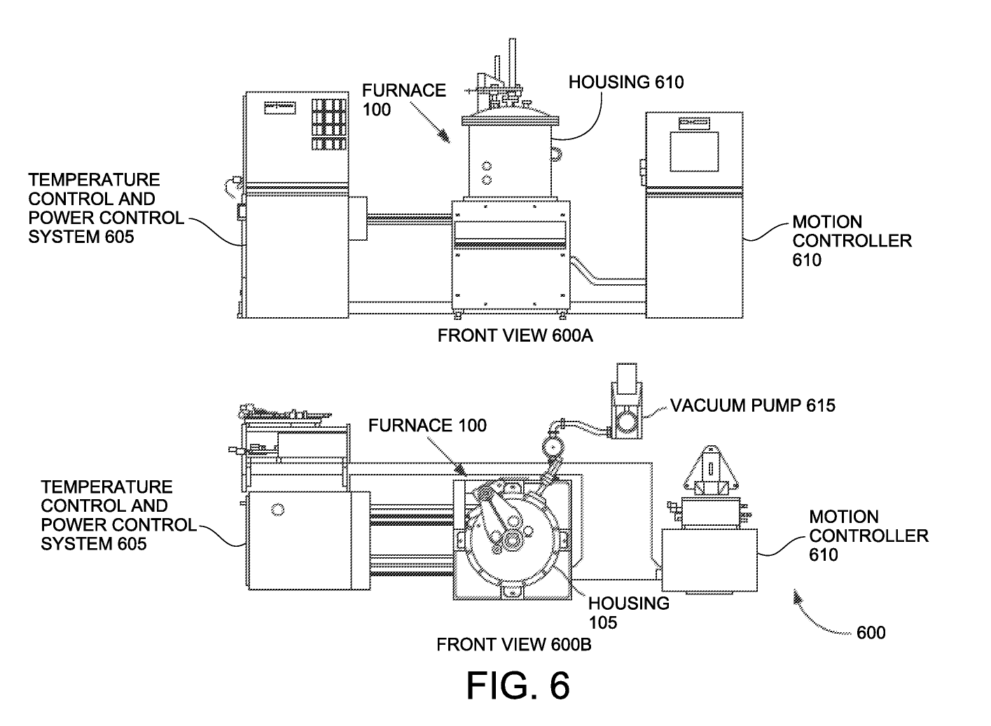

FIG. 6 is a schematic diagram illustrating a controlled heat extraction system (CHES) 600 with the furnace 100A, such as those shown in FIG. 1A, used in growing the single crystal along the c-axis, according to one embodiment. In particular, FIG. 6 illustrates a front view 600A and a top view 600B of the CHES 600 used in growing the single crystal. The front view 600A and the top view 600B together illustrate various components of the CHES 600. As illustrated, the CHES 600 may include the furnace 100A with the housing 105, a temperature control and power control system 605, a motion controller 610 and a vacuum pump 615. As mentioned above, the furnace 100A for growing crystals may include the seed cooling component 120 along with the crucible 150, the heating element(s) 125, the insulating element 130 and the GCD 135 enclosed in the housing 105. The temperature control and power control system 605 is configured to precisely control the temperature of the heating element(s) 125 within an average at least ranging from −0.2° C. to +0.2° C. In one example embodiment, temperature control and power control system 605 controls the temperature of the heating element(s) 125 such that the charge material 145 is heated above the melting temperature of the charge material 145. In another example embodiment, the temperature control and power control system 605 controls the temperature of the heating element(s) 125 such that the temperature of the heating element(s) 125 is substantially lowered at a rate of 0.02 to 5° C./hr.

The motion controller 610 is configured to control the movement of the seed cooling component 120 along with the crucible 150. For example, the motion controller 610 lowers the seed cooling component 120 along with the crucible 150 to maintain the growth rate of the crystal. The motion controller 610 is also configured to control the position of the GCD 135. For example, the motion controller 610 moves the GCD 135 over a range of positions to maintain the growth rate of the crystal. It can be noted that, the motion controller 610 is configured to independently control the movement of the seed cooling component 120 and the position of the GCD 135

The vacuum pump 615 creates and maintains a vacuum (e.g., partial vacuum or full vacuum) inside the housing 105 such that the crystal can be grown in a controlled atmosphere. It can be noted that, the furnace 100A in the CHES 600 can also grow crystals under partial gas pressures. Although the above description of the CHES 600 is made with respect to the furnace 100A, one can envision that the CHES 600 may also use the furnace 100B or the furnace 100C for growing the single crystals along the c-axis.

While the above description is generic for crystal growth from the melt different processes use different approaches to achieve the desired results with different materials. For example, industrial processes, such as, Czochralski and Kyrapolous melt the charge material 145 in a crucible 150 and then dip a single crystal seed crystal 140 near the surface of the melt for “seeding”; thereafter crystal growth may be achieved by controlled pulling or growing below the surface or a combination of both. Other processes, such as, Bridgman, Gradient Freeze, Heat Exchanger Method, etc., load the seed crystal 140 and the charge material 145 together in the crucible 150; it is important that the seed crystal 140 is partially melted back which is achieved by controlling temperature gradients so that during ‘seeding’ a portion of the seed crystal 140 in contact with the melt is melted without melting out the seed crystal 140 completely. This is achieved while the melt is heated above its melting temperature.

In CHES furnaces a single crystal seed crystal 140 is centered at the bottom of the crucible 150 and the charge material 145 is placed on top of the seed crystal 140 filling the crucible 150. The crucible 150 is positioned on the heat extraction seed cooling component 120 mounted at the bottom of the furnace with the closed end of the seed cooling component 120 near the bottom of the heating element of the heat zone. Under controlled conditions heat is applied to melt the charge material 145; the seed crystal 140 is cooled by helium cooling through the heat extraction seed cooling component 120. Under these conditions, seeding conditions first melt back the seed crystal 140, where the solid-liquid interface is the isotherm corresponding to the melting point of sapphire. Above this isotherm the melt is above melting point of sapphire with a temperature gradient in the liquid. Below the isotherm is temperature gradient in the solid. For proper seeding the seed crystal 140 must be melted back partially, and there should not be remnants of the charge material 145 in solid form. Further, a slightly convex solid-liquid interface is desirable. However, all these conditions have to occur at the bottom of the crucible 150, which is not easy to observe directly. Reproducibility and accuracy are very important to build a production process, so techniques for improving inspection and control of the seeding process, as disclosed below, are important.

Proper ‘seeding’ is essential so that the grown boule maintains the atomic arrangement of the seed crystal 140; this determines the orientation of the boule. Single crystal growth requires precise control of variables, and variation can result in growth of a different orientation (as with unseeded growth) and this spurious nucleation can result in growth of another grain of different orientation. For isotropic materials, such as silicon, spurious nucleation results in growth of many grains, or multi-crystalline growth. However, in anisotropic materials, such as sapphire, if multiple grains are formed it can result in cracking of the boule during cool down. Therefore, it is preferred that complete single crystal growth is nucleated, and growth of this orientation is maintained. Anything that can achieve precise control of variables during ‘seeding’ and growth is beneficial for growth of crystals, such as sapphire boules. The historical challenges of precise control may be responsible for the fact that in industry a-, m- and r-orientation boules are grown routinely, but c-axis boules have not been produced on commercial basis. The CHES process and systems disclosed herein may be used to grow c-axis orientation sapphire boules routinely and consistently.

For the CHES process “seeding” is at the bottom of the crucible 150 under the surface of the melt and is not visible. During the melting of the charge material 145 melting starts in the crucible 150, and the liquid runs down towards the bottom of the crucible 150. As melting progresses the charge material 145 towards the middle and top starts melting and more melt continues to go towards the bottom of the crucible 150. Further melting raises the liquid level in the crucible 150 until it goes above the solid charge material 145. Then the remaining charge material 145 melts until there is no more solid charge material 145 left. The melt wets the cooled seed crystal 140 and starts melting back the seed crystal 140. The goal is to melt the entire charge material 145 and melt back a portion of the seed crystal 140 prior to start of growth.

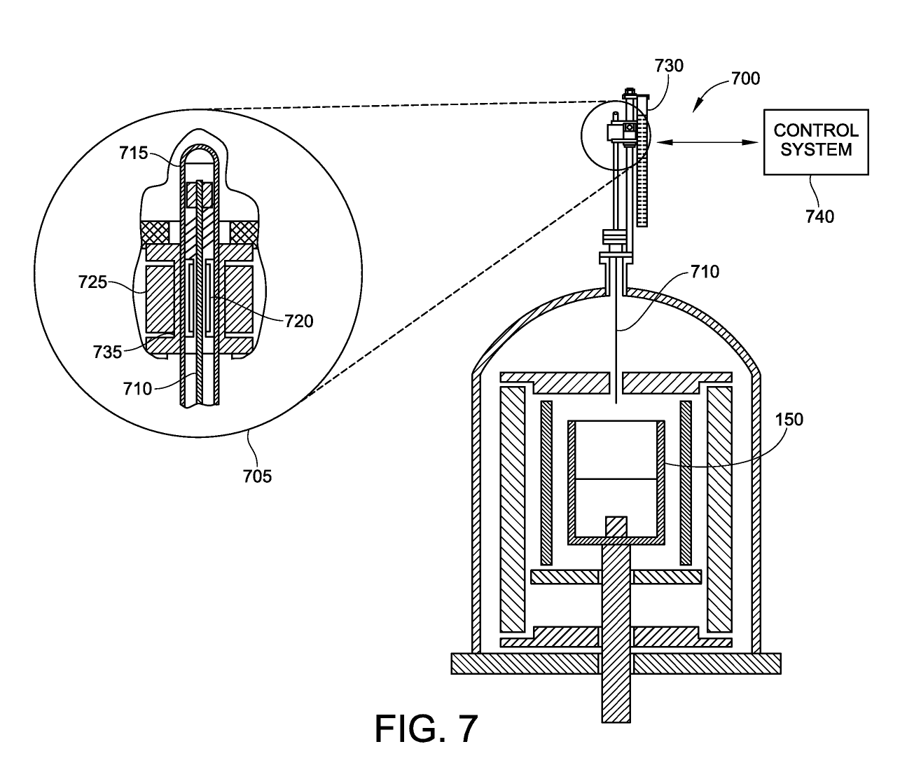

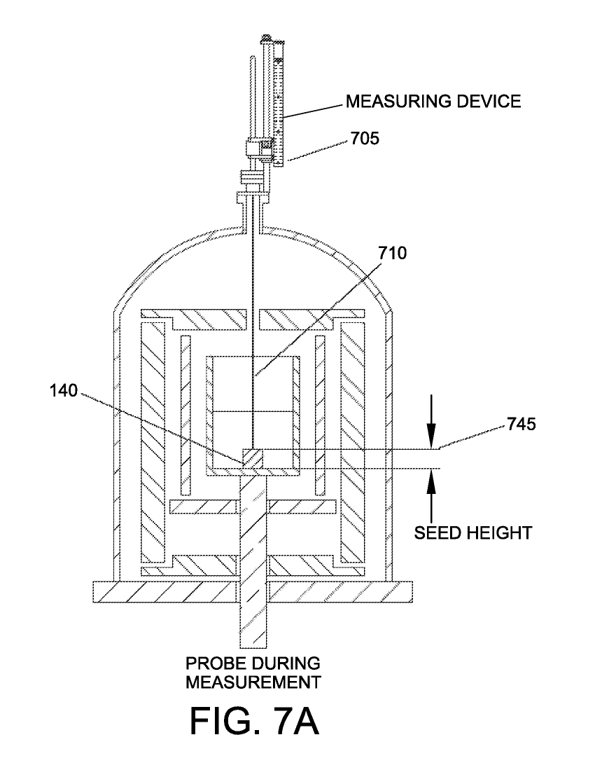

In CHES furnaces observation or inspection of the melting behavior may be accomplished using an inspection facility 700, which in embodiments may involve direct, mechanical inspection (such as using a probe system within the heat zone of the chamber), by visual inspection, such as through a window, or by instrument-based inspection, such as by a sensor within or outside the heat zone of the chamber. Referring to FIG. 7, one embodiment of an inspection facility 700 is a mechanical probe 705. The probe 705, which may include a refractory metal filament (such as tungsten, tungsten-molybednum alloys, etc.) may be mounted at the top port of the furnace and lowered inside the heat zone into the crucible 150. When the probe hits solid material, resistance is felt. This registers the position of the solid liquid interface. If the probe is calibrated during setting up of the crucible 150, the probe data will yield not only melting of charge material 145 but also top of the seed crystal 140, followed by melting back of the seed crystal 140. After proper seeding, growth is initiated and probe data can be used to monitor the position of the growth interface. The probe data with feedback control can be used to control growth directly rather than using indirect means used with conventional crystal growth processes. The probe system is optionally designed using a tungsten filament mounted on a carriage on rails, so it can be lowered until it contacts the solids. The sensitive probe is sensitive to resistance felt on contacting solids. This slight resistance sensitivity does not perturb the interface during melt down or growth. Such a probe can be with manual operation or automated with programming to probe at desired intervals. Depicted as a logical element in FIG. 7 is a control system 740, which it should be understood may include various hardware, software, and other elements suitable for automated control of various system components and processes disclosed throughout this disclosure, such as controlling the mechanical probe 705 shown in FIG. 7, but also for automated control of power (and related temperature control) during heating and cooling phases, automated inspection of the charge material 145 or seed crystal 140, automated application of power and time-based algorithms for crystal growth, or the like.

Referring still to FIG. 7, a mechanical probe 705 is illustrated that is used to inspect the seed crystal 140 status. A tungsten rod 710 can be used as a probe that is dipped into the liquid melt of the charge material 145 to touch the solid crystalline surface of the seed crystal 140 during melting to make sure that some, but not all, of the seed crystal 140 is melted. The probe 705 can also be used to measure growth rate of the crystal after the seed stage. Such later use is optional, as it may risk breaking or damaging the crystal. In an embodiment the probe 705 may include a tube 715 (e.g., made of quartz) with the tungsten rod 710 suspended from a first, interior magnet 720. A second, outer magnet 725 external to the chamber can control the first magnet 720 inside the chamber to allow the user to manipulate the tungsten rod 710 without requiring a hole in the chamber. There are therefore two magnetically coupled elements, with the outer magnet 725 being placed on a facility for moving it, such as a linear motor 730. The system may have a sensor 735 that looks across the bottom of the rod 710 and as the rod 710 and inner magnet 720 go down together. When the rod 710 hits the seed crystal 140, the sensor 735 senses when inner magnet 720 has gone out of the field of view within the chamber or has entered the field of view on top. When there is a relative difference, it can be observed that the rod 710 is slowing down as a result of having contacted the seed crystal 140. FIG. 7A shows the probe 705 during measurement, with the probe rod 710 touching the top of the seed crystal 140, allowing measurement of the seed height 745, which is equal to the displacement of the probe rod 710 relative to another element of the probe 705.

CHES furnaces are designed to control crystal growth on the basis of power or temperature. The control circuit may be designed to match the desired set point with the measured values. In case of temperature control a sensor may be used to measure temperature. These sensors, which may comprise elements of various embodiments of an inspection facility 700, may be pyrometers, thermocouples, etc. At high temperatures for sapphire crystal growth (in excess of 2040° C.) thermocouples are very fragile, less reliable, and tend to drift with time, hence they are not conveniently used for precise control of the temperatures in the furnace. Pyrometers rely on the infrared signal from the hot body to measure temperature; they have to be aligned accurately and can be affected by deposition on the viewing windows during high temperature operation. Pyrometers are typically not sensitive below about 800° C., because of the low intensity of the infrared signal at those temperatures. Between power control and temperature control, temperature control is more precise at the high temperatures of seeding and growth of sapphire. Moreover, temperature control is less susceptible to change during degradation of the heat zone with use. CHES furnace controls may rely on power control at low temperatures and temperature control at higher temperatures. During the heat up stage power and temperature are monitored, and control is designed to switch from power to temperature control at a pre-designated temperature. Similarly, during cool down the control changes from temperature to power control at appropriate temperatures.

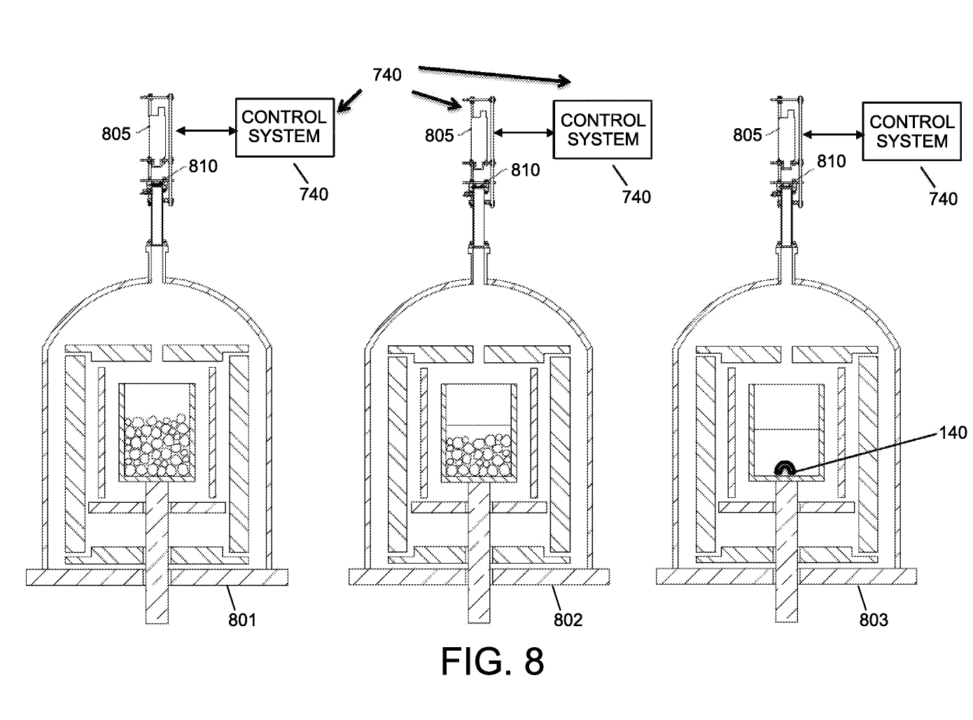

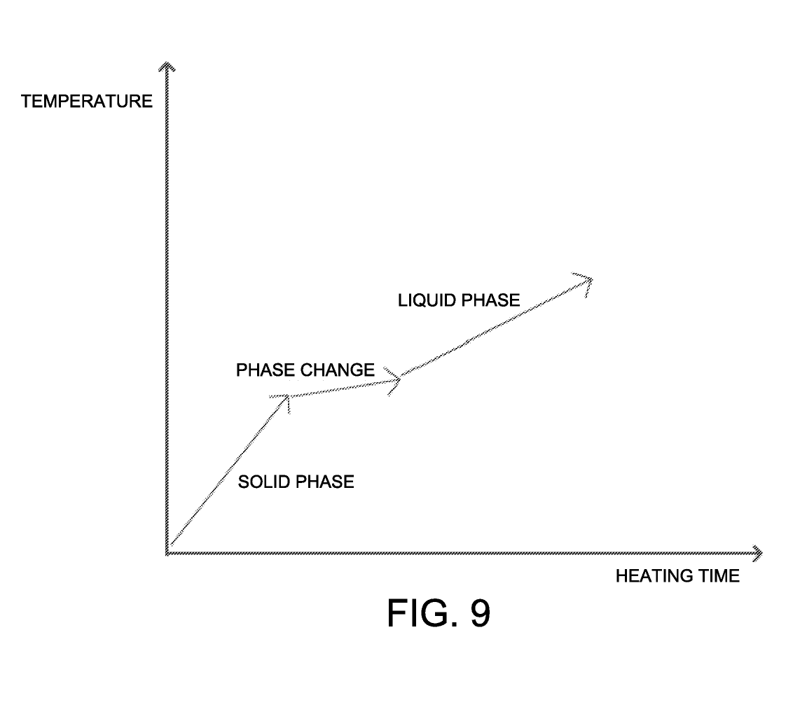

Within the various embodiments disclosed herein it is preferable in some cases to build in internal calibrations to improve the accuracy and reproducibility of temperature control. FIG. 8 shows a set of views of a pyrometer 805 used as an external inspection facility 700 for automating elements of power and temperature control in a crystal growth method. In embodiments a specially designed pyrometer 805 may be used for this method. The pyrometer 805, when the charge material 145 melts, looks at chunks of crackle in the charge material 145, seeking to measure a change of emissivity of the surface as the charge material 145 begins to make a phase change between solid phase and liquid phase. The view 801 shows the unmelted charge material 145. The view 802 shows a partial melt of the charge material 145. The view 803 shows a nearly complete melt of the charge material 145 into the liquid phase, leaving only a portion of the melted back seed crystal 140. During melting, the latent heat of fusion of the charge material 145 is expected to change because of the phase change. Referring to FIG. 9, as the charge material 145 and seed crystal 140 are heated, the temperature slows its increase during the phase change (it is relatively constant for a period before proceeding further upward in the liquid phase). Once in the liquid phase, an observer of the process can see the temperature go up again. Thus, the first derivative of temperature curve spikes at the melting point, so one can observe when that phase change is happening. Once that change is observed enough times, the observer can develop an algorithm that indicates what extent of power (for heating) over what duration is likely to bring a given amount of charge material 145 to the point from beginning to melt to achieving melt back of the seed crystal 140. This allows the system to define the beginning point of the melting, which in turn allows one to interpolate an algorithm to melt and re-solidify. Referring again to FIG. 8, the pyrometer 805 can measure a change of emissivity of the grown crystal as it grows past the surface of the melt without needing to touch anything. The pyrometer gives end points of temperature, with gaps being filled by experiment and interpolation. In embodiments two pyrometers 805 may be used. The first pyrometer 805 may be mounted at the top of the chamber to inspect the interior of the chamber, in particular the heat zone of the chamber where the charge material 145 and seed crystal component 140 reside. A second, side pyrometer may be mounted on the side of the chamber and may be focused on the crucible containing the charge material 145, but not aimed to see the seed crystal component 140 directly. Therefore, the first pyrometer 805 may be used to look at the emissivity change from solid to liquid during melting and also from liquid to solid toward the end of solidification. During heating, as the pyrometer 805 sees the first signs of melting, it shows a change of slope. As more melting occurs, the pyrometer 805 shows flattening, as in FIG. 9. When the pyrometer 805 sees a complete molten surface, the emissivity data starts to rise again, with a different slope as shown in FIG. 9. At different points in the process, the same pyrometer 805 may detect ‘start of melting’ and ‘end of solidification’. At the start of melting there can be solid charge material 145 under the surface which has to be melted, and the seed component 140 may still need to be melted back partially before homogenization and initiation of crystal growth. The side pyrometer (not shown in FIG. 8) may be directed at the crucible, rather than the charge material 145. In this configuration the side pyrometer does not register the emissivity change. The side pyrometer may be used to control the temperature of the furnace. Pyrometers on an absolute basis are not always highly accurate; however, when the first pyrometer 805 observes an initial change in the slope of emissivity, it may be inferred that the charge material 145 is at the melting point of sapphire (2040 C). This allows calibration of the side pyrometer, such that if it is reading higher or lower than 2040 C at that point in the process, a factor may be subtracted or added to its readings throughout the process to obtain a more accurate measurement of the temperature in the heat zone of the chamber. Similar approaches may be used at the end of solidification, where the first pyrometer 805 observes an emissivity change as the liquid disappears. Over a period of runs of the CHES process, it is possible to generate data about how long it takes for a given size of crystal to solidify. This data can be used in automated portions of the crystal growth process. A window 810 may be used for the pyrometer 805 to look into the heat zone of the chamber to get to the charge material 145. During melting of charge material 145 heat input is used mainly for the latent heat of fusion. After most of the charge material 145 is molten, heat input is for increasing the temperature of the charge material 145. CHES furnace controls heat the charge material 145 at a fast rate up to observation (by pyrometer 805 viewing surface of charge material 145) of start melting, and then heat input is reduced until ‘end of melting’ is determined by the signal from the pyrometer 805 (which may the same pyrometer 805 or, in other embodiments, another one). Thereafter, subject to other controls, such as under a software-based control system 740, after achieving optimum seeding conditions, growth can be initiated. Precise controlled solid and liquid temperature gradients and growth interface are preferably maintained to avoid spurious nucleation. Similar to start of melting sensed by the pyrometer 805, when the solid sapphire crystal breaks the surface during growth the change in emissivity observed by the pyrometer 805 is used by control instrumentation to signal end of growth as an internal calibration.

Pyrometers are sensitive instruments, and it is preferable to focus the objective on the target. If the pyrometer 805 is removed from the furnace to clean the window, then the pyrometer 805 has to be aligned/adjusted/focused for each growth run. However, if the window is mounted such that it can be cleaned without disturbing the pyrometer 805, more accuracy can be obtained with less work. This, as seen in FIG. 8, the pyrometer 805 may be mounted such that the window 810 may be cleaned without moving or removing the pyrometer 805.

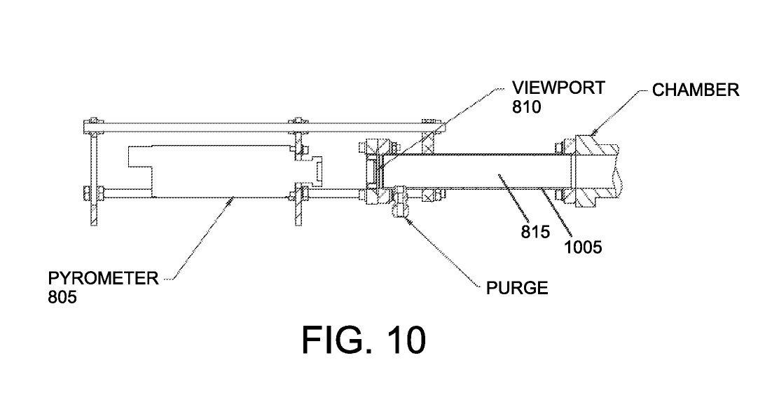

Referring to FIG. 10, a window purging design is illustrated for use in connection with the pyrometer 805. In connection with using the pyrometer 805 to inspect the seed crystal 140, out-gassing can occur that occludes the inspection window 810 for the heat zone of the chamber. As an observer looks through the window 810 to read what is happening, deposition on the window 810 from the heat zone of the chamber can cause wrong readings outside the heat zone of the chamber. To reduce the impact of out-gassing, a tube 1005 may be extended from the window 810 within the heat zone of the chamber, defining a region 815 into which an inert gas, such as argon, may be flowed to prevent deposition on the window that is used for pyrometer 805 or other sensing device to inspect the heat zone of the chamber. As the length of the tube 1005 is extended, deposition on the window may be reduced. As the pressure of flow of the inert gas is increased, deposition on the window 810 becomes less. The tube 1005 or similar facility creates a local environment that is a bit like an air curtain, putting pressure in localized place with a small amount of inert gas flow. The extension tube 1005 from the pyrometer 805 also gets the vapor to deposit on the tube, rather than the viewport window 810, so that the small amount of vapor does not end up on the window 810. Note that the window 810 is mounted separately from the pyrometer 805, so that it can be cleaned without moving the pyrometer 805. Related to window 810 may be a way of detecting how much coloration change has occurred in the window or the extent of deposits on the window in order to decide whether to clean the window 810 or not. A sensor on window 810 may compare to a chart, such as in software, to inform when the window 810 is dirty and the system isn't allowing good readings through the window 810. The sensor detects cleanliness of the window 810, deposit density, and the like. To measure the cleanliness of the lens, one can look at what is going on from the outside and see what is changing. For example, a target may be placed inside the heat zone of the chamber, such as on the back side of the heat zone of the chamber. A goal may be to have no deposition (such as using the tube 1005 and gas flow), or, if deposition present, to observe it by seeing changes in how the target is viewed through the window 810.

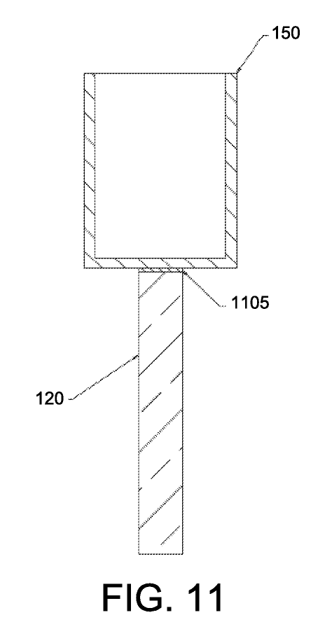

In CHES configuration the crucible 150 is placed on the seed cooling component 120 projecting into the heat zone. Both the crucible 150 and seed cooling component 120 are made of refractory metals, such as tungsten. At high temperatures of sapphire crystal growth over prolonged periods and under load the crucible 150 and seed cooling component 120 can fuse together. This can lead to breakage of seed cooling component 120 and/or crucible 150. Referring to FIG. 11, a plate 1105 between the seed cooling component 120 and the crucible 150 is illustrated. The plate 1105, intended to avoid fusion of seed cooling component 150 and the crucible 150. In certain preferred embodiments of a sapphire crystal growth system, both the seed cooling component 120 and the crucible 150 are made of tungsten. As a result, the seed cooling component 120 and crucible 150 can have both thermal and mass transfer at very high temperatures, such as during the heating of the charge material 145. It may be preferred in some situations to have insulating high temperature, different material layer, such as the plate 1105, between the seed cooling component 120 and crucible 150, one embodiment of which would be a thin layer or disk of a material, such as molybdenum, between the seed cooling component 120 and crucible 150, which acts as an “washer” between them. Use of a thin molybdenum disc between the seed cooling component 120 and crucible 150 has been an improvement in minimizing the fusion. Another approach is to coat the molybdenum disc with refractory oxides, such as, alumina, yttria, zirconia, yttria stabilized zirconia, etc., which can also prevent fusion.

Refractory metal crucibles are used for sapphire crystal growth. One of the methods of forming these crucibles is spinning at high temperatures. The preferred shape with such a process is cylindrical shape. Another approach is to press and sinter, followed by machining to final dimensions. This process lends itself to more varied shapes, including rectangular and square. In the CHES approach, crystals are grown with the growth axis aligned with the c-axis of sapphire. However, the finished wafers are specified as circular c-axis wafers with, the a-axis flat for indexing during further processing. Using square or rectangular crucible 150s, the seed crystal 140 can be positioned such that its a-axis is orthogonal to one of the flat sides of the crucible 150. After crystal growth, the a-axis can be identified with ease for further processing of the boule.

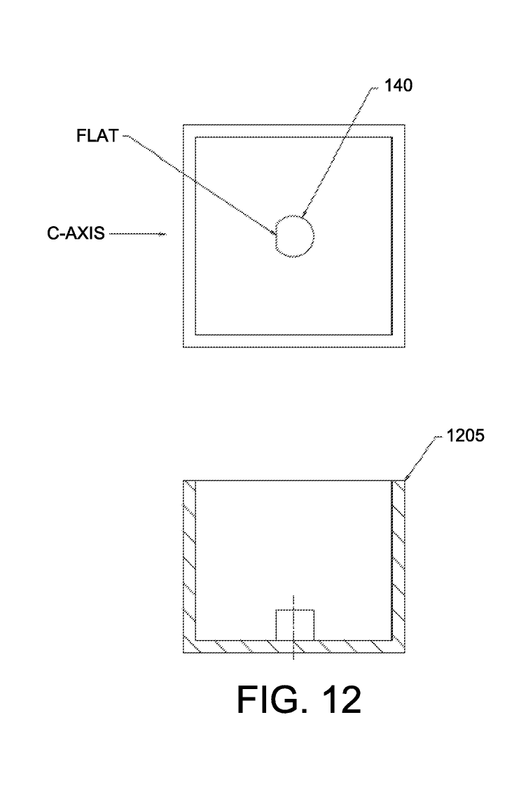

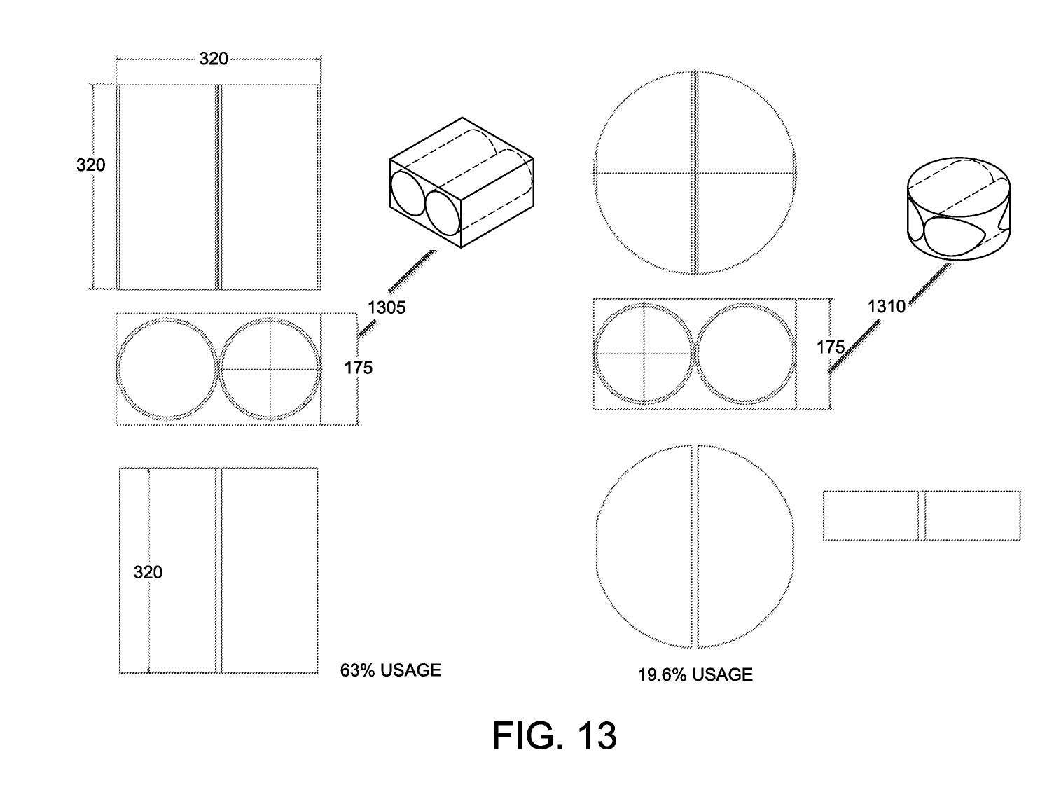

Conventional crystal growth processes grow cylindrical a-axis or m-axis sapphire boules in circular crucibles, then core orthogonal to the growth axis to produce c-axis cores. For a circular, cylindrical boule, with production of nearly circular cores, this results in substantial loss at both ends of the core. As the requirement of cores progresses towards larger diameters this loss increases. If the seed crystal 140 prior to growth of boules is oriented so that the desired core axis is orthogonal to one of the sides of square or rectangular crucible 150, this loss of material at ends of cores will be minimized. Other advantages of this approach are (i) ease of identification of coring direction after the boule is grown, and (ii) equal length cores for ease of handling and automation in large scale production. C-axis growth, although it has significant advantages, can be challenging, because of the crystal structure. In alternative embodiments, the methods and systems described herein can be used for a-axis crystal growth. FIG. 12 illustrates an alternative shape for a crucible 150 in a crystal growth system. As shown in FIG. 12, if one grows a square crystal on the a-axis, with the seed oriented so that the c-axis is orthogonal to the flat side of the crucible, one can core the c-axis from the side of the resulting sapphire boule without losing the corners out of the material. This has the potential benefit of faster cycle time (a-axis processes may be faster in some cases) plus improvement of yield relative to the cylindrical shape for the crucible 150. Also, this process provides easy identification of the c-axis in the growth crystal. Thus, in certain embodiments it may be preferred to use a non-circular crucible 1205, such as using a crucible that is a rectangular solid shape. Used in the embodiments disclosed herein, such a crucible could be used to grow a-axis crystals and fully automate it both crystal growth and coring of the resulting boule, removing uncertainties involved in current sapphire crystal growth processes. FIG. 13 illustrates material saved by using non-circular crucible shapes. The views 1305 of a boule made from a non-round crucible show that cylindrical cores may be taken from a rectangular solid boule with relatively little material lost, while the views 1310 of a cylindrical boule made from a cylindrical, circular crucible require sacrifice of significant amounts of material to produces cylindrical cores. It may be noted that in alternative embodiments a non-round crucible could be used for c-axis growth, with a seed crystal oriented to facilitate a-axis growth orthogonal to a flat side of the crucible. This would make the a-axis position easily identifiable in the growth crystal and potentially obviate the need for a flat element that is currently used in c-axis sapphire wafers to indicate the a-axis. (The flat element is typically orthogonal to the a-axis in current wafers).

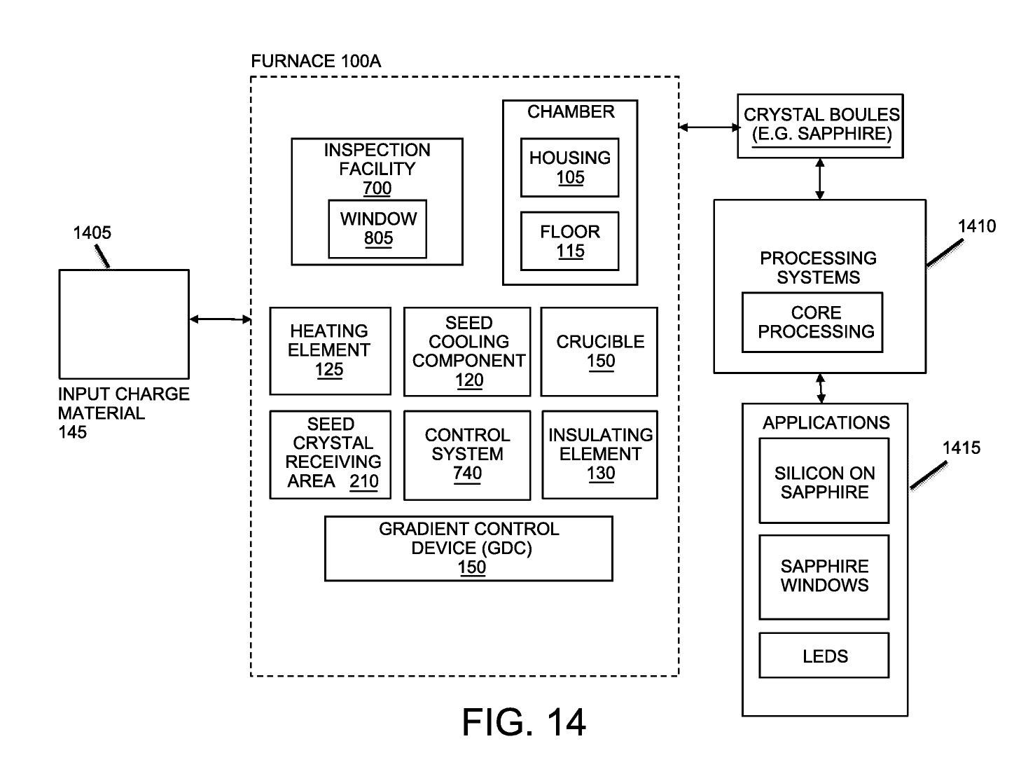

FIG. 14 provides a logical view of certain methods and systems as disclosed herein, including the CHES furnace 100A, with functional components including a housing 105, chamber (formed by housing part 110 and floor 115), seed cooling receiving area 210, inspection facility 700, seed cooling component 120, heating elements 125, insulating elements 125, gradient control device 135 and crucible 150. Thus it may be understood that the structural view of FIG. 1A, while representing one preferred embodiment, may be just one of various configurations that include the logical elements for making a CHES furnace 100A suitable for crystal growth, such as sapphire crystal growth. Alternative embodiments, such as involving different chamber and crucible shapes (such as the non-round crucibles described in connection with FIG. 12), different inspection systems 700 (such as internal, mechanical systems, sensors, or external systems), various automation or control systems 740 (such as for automating probes, pyrometer-based processes, algorithm-based heating and cooling, safety features, security features, or the like), various configurations of heat shields and thermal transfer elements, may be envisioned and are intended to be encompassed herein. Also depicted in FIG. 14 are elements of input systems 1405 for creating charge material 145, such as alumina crackle for sapphire crystal growth, as well as processing systems 1410 for processing the sapphire boules that are an output of the CHES furnace 104A, such as systems for producing cores of crystal (e.g., sapphire cores) suitable in size, shape, and crystal orientation for various applications 1415, such as LEDs, substrates for silicon-on-sapphire wafers, or sapphire windows.

Although the foregoing description is made with reference to growing a single crystal along the c-axis, the methods and systems described herein can be implemented for growing single crystals along other axis such as a-axis, r-axis or m-axis. In various embodiments, the methods and systems described in the figures, enable growing of high yield c-axis crystals with low defects and bubbles using a combination of features. The combination of features range from 30-75% seed crystal cooling, 10-30% melt cooling, 10-30% crucible lowering, and 10-30% temperature gradient control. The above-described CHES system and the processes result in high yield during manufacturing of c-cut wafers because of the c-axis growth process. This helps in substantially reducing the wafer cost while retaining high structural perfection. The above-described CHES can also be used for growing several other types of crystals in optics and semi-conductor applications.

The methods and systems described herein, in particular for performing various automation and control functions ascribed to the control systems 740, may be deployed in part or in whole through a machine that executes computer software, program codes, and/or instructions on a processor. The processor may be part of a server, client, network infrastructure, mobile computing platform, stationary computing platform, or other computing platform. A processor may be any kind of computational or processing device capable of executing program instructions, codes, binary instructions and the like. The processor may be or include a signal processor, digital processor, embedded processor, microprocessor or any variant such as a co-processor (math co-processor, graphic co-processor, communication co-processor and the like) and the like that may directly or indirectly facilitate execution of program code or program instructions stored thereon. In addition, the processor may enable execution of multiple programs, threads, and codes. The threads may be executed simultaneously to enhance the performance of the processor and to facilitate simultaneous operations of the application. By way of implementation, methods, program codes, program instructions and the like described herein may be implemented in one or more thread. The thread may spawn other threads that may have assigned priorities associated with them; the processor may execute these threads based on priority or any other order based on instructions provided in the program code. The processor may include memory that stores methods, codes, instructions and programs as described herein and elsewhere. The processor may access a storage medium through an interface that may store methods, codes, and instructions as described herein and elsewhere. The storage medium associated with the processor for storing methods, programs, codes, program instructions or other type of instructions capable of being executed by the computing or processing device may include but may not be limited to one or more of a CD-ROM, DVD, memory, hard disk, flash drive, RAM, ROM, cache and the like.

A processor may include one or more cores that may enhance speed and performance of a multiprocessor. In embodiments, the process may be a dual core processor, quad core processors, other chip-level multiprocessor and the like that combine two or more independent cores (called a die).

The methods and systems described herein may be deployed in part or in whole through a machine that executes computer software on a server, client, firewall, gateway, hub, router, or other such computer and/or networking hardware. The software program may be associated with a server that may include a file server, print server, domain server, internet server, intranet server and other variants such as secondary server, host server, distributed server and the like. The server may include one or more of memories, processors, computer readable media, storage media, ports (physical and virtual), communication devices, and interfaces capable of accessing other servers, clients, machines, and devices through a wired or a wireless medium, and the like. The methods, programs or codes as described herein and elsewhere may be executed by the server. In addition, other devices required for execution of methods as described in this application may be considered as a part of the infrastructure associated with the server.

The server may provide an interface to other devices including, without limitation, clients, other servers, printers, database servers, print servers, file servers, communication servers, distributed servers and the like. Additionally, this coupling and/or connection may facilitate remote execution of program across the network. The networking of some or all of these devices may facilitate parallel processing of a program or method at one or more location without deviating from the scope of the invention. In addition, any of the devices attached to the server through an interface may include at least one storage medium capable of storing methods, programs, code and/or instructions. A central repository may provide program instructions to be executed on different devices. In this implementation, the remote repository may act as a storage medium for program code, instructions, and programs.

The software program may be associated with a client that may include a file client, print client, domain client, internet client, intranet client and other variants such as secondary client, host client, distributed client and the like. The client may include one or more of memories, processors, computer readable media, storage media, ports (physical and virtual), communication devices, and interfaces capable of accessing other clients, servers, machines, and devices through a wired or a wireless medium, and the like. The methods, programs or codes as described herein and elsewhere may be executed by the client. In addition, other devices required for execution of methods as described in this application may be considered as a part of the infrastructure associated with the client.

The client may provide an interface to other devices including, without limitation, servers, other clients, printers, database servers, print servers, file servers, communication servers, distributed servers and the like. Additionally, this coupling and/or connection may facilitate remote execution of program across the network. The networking of some or all of these devices may facilitate parallel processing of a program or method at one or more location without deviating from the scope of the invention. In addition, any of the devices attached to the client through an interface may include at least one storage medium capable of storing methods, programs, applications, code and/or instructions. A central repository may provide program instructions to be executed on different devices. In this implementation, the remote repository may act as a storage medium for program code, instructions, and programs.

The methods and systems described herein may be deployed in part or in whole through network infrastructures. The network infrastructure may include elements such as computing devices, servers, routers, hubs, firewalls, clients, personal computers, communication devices, routing devices and other active and passive devices, modules and/or components as known in the art. The computing and/or non-computing device(s) associated with the network infrastructure may include, apart from other components, a storage medium such as flash memory, buffer, stack, RAM, ROM and the like. The processes, methods, program codes, instructions described herein and elsewhere may be executed by one or more of the network infrastructural elements.

The methods, program codes, and instructions described herein and elsewhere may be implemented on a cellular network having multiple cells. The cellular network may either be frequency division multiple access (FDMA) network or code division multiple access (CDMA) network. The cellular network may include mobile devices, cell sites, base stations, repeaters, antennas, towers, and the like. The cell network may be a GSM, GPRS, 3G, EVDO, mesh, or other networks types.

The methods, programs codes, and instructions described herein and elsewhere may be implemented on or through mobile devices. The mobile devices may include navigation devices, cell phones, mobile phones, mobile personal digital assistants, laptops, palmtops, netbooks, pagers, electronic books readers, music players and the like. These devices may include, apart from other components, a storage medium such as a flash memory, buffer, RAM, ROM and one or more computing devices. The computing devices associated with mobile devices may be enabled to execute program codes, methods, and instructions stored thereon. Alternatively, the mobile devices may be configured to execute instructions in collaboration with other devices. The mobile devices may communicate with base stations interfaced with servers and configured to execute program codes. The mobile devices may communicate on a peer to peer network, mesh network, or other communications network. The program code may be stored on the storage medium associated with the server and executed by a computing device embedded within the server. The base station may include a computing device and a storage medium. The storage device may store program codes and instructions executed by the computing devices associated with the base station.

The computer software, program codes, and/or instructions may be stored and/or accessed on machine readable media that may include: computer components, devices, and recording media that retain digital data used for computing for some interval of time; semiconductor storage known as random access memory (RAM); mass storage typically for more permanent storage, such as optical discs, forms of magnetic storage like hard disks, tapes, drums, cards and other types; processor registers, cache memory, volatile memory, non-volatile memory; optical storage such as CD, DVD; removable media such as flash memory (e.g., USB sticks or keys), floppy disks, magnetic tape, paper tape, punch cards, standalone RAM disks, Zip drives, removable mass storage, off-line, and the like; other computer memory such as dynamic memory, static memory, read/write storage, mutable storage, read only, random access, sequential access, location addressable, file addressable, content addressable, network attached storage, storage area network, bar codes, magnetic ink, and the like.

The methods and systems described herein may transform physical and/or or intangible items from one state to another. The methods and systems described herein may also transform data representing physical and/or intangible items from one state to another.

The elements described and depicted herein, including in flow charts and block diagrams throughout the figures, imply logical boundaries between the elements. However, according to software or hardware engineering practices, the depicted elements and the functions thereof may be implemented on machines through computer executable media having a processor capable of executing program instructions stored thereon as a monolithic software structure, as standalone software modules, or as modules that employ external routines, code, services, and so forth, or any combination of these, and all such implementations may be within the scope of the present disclosure. Examples of such machines may include, but may not be limited to, personal digital assistants, laptops, personal computers, mobile phones, other handheld computing devices, medical equipment, wired or wireless communication devices, transducers, chips, calculators, satellites, tablet PCs, electronic books, gadgets, electronic devices, devices having artificial intelligence, computing devices, networking equipments, servers, routers and the like. Furthermore, the elements depicted in the flow chart and block diagrams or any other logical component may be implemented on a machine capable of executing program instructions. Thus, while the foregoing drawings and descriptions set forth functional aspects of the disclosed systems, no particular arrangement of software for implementing these functional aspects should be inferred from these descriptions unless explicitly stated or otherwise clear from the context. Similarly, it will be appreciated that the various steps identified and described above may be varied, and that the order of steps may be adapted to particular applications of the techniques disclosed herein. All such variations and modifications are intended to fall within the scope of this disclosure. As such, the depiction and/or description of an order for various steps should not be understood to require a particular order of execution for those steps, unless required by a particular application, or explicitly stated or otherwise clear from the context.

The methods and/or processes described above, and steps thereof, may be realized in hardware, software or any combination of hardware and software suitable for a particular application. The hardware may include a general purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or instead, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices, as well as heterogeneous combinations of processors, processor architectures, or combinations of different hardware and software, or any other machine capable of executing program instructions.

Thus, in one aspect, each method described above and combinations thereof may be embodied in computer executable code that, when executing on one or more computing devices, performs the steps thereof In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

Although the present embodiments have been described with reference to specific example embodiments, it will be evident that various modifications and changes may be made to these embodiments without departing from the broader spirit and scope of the various embodiments. In addition, it will be appreciated that the various operations, processes, and methods disclosed herein may be may be performed in any order. Accordingly, the specification and drawings are to be regarded in an illustrative rather than a restrictive sense.

What is claimed is:

1. A method for growing a sapphire crystal, comprising:
using a pyrometer to observe a source material during heating of the source material;
observing, based on a change in emissivity of the surface source material, a phase change in the source material; and
using the observed phase change to determine an amount of heating required to induce the phase change.

2. The method of claim 1, further comprising using a second pyrometer to obtain additional information about the source material.

3. The method of claim 1, further comprising repeating a plurality of observations and using the observations to develop a heating algorithm that predicts heating time and amount required to melt the source material completely and achieve controlled melting of a seed crystal.

4. The method of claim 1, wherein a first derivative of a temperature curve of the source material is used to determine a point of the phase change.

5. The method of claim 1, further comprising deploying the pyrometer in proximity to a window of a sapphire crystal growth furnace to facilitate observation of sapphire crystal growth source material.

6. The method of claim 5, further comprising deploying the pyrometer such that the window may be cleaned without moving the pyrometer.

7. The method of claim 5, further comprising deploying the phase change of the source material as a calibration to facilitate calibration of the pyrometer.

8. The method of claim 5, wherein the sapphire crystal growth furnace is used in a c-axis sapphire crystal growth process.

9. The method of claim 8, wherein the process is a controlled heat extraction process.

10. The method of claim 1, further comprising controlling at least one of power and temperature in a controlled heat extraction sapphire crystal growth process based on readings from the pyrometer.

11. The method of claim 10, wherein the crystal growth process is a c-axis crystal growth process.

12. The method of claim 11, wherein the process is a controlled heat extraction process.

13. A method for growing a sapphire crystal, comprising:
using a pyrometer to observe a source material during at least one of melting and solidification of the source material;
observing, based on a change in emissivity of the surface source material, a phase change in the source material; and
using the observed phase change to trigger at least one of the initiation and the termination of a portion of a crystal growth process.

14. A method for growing a sapphire crystal, comprising:
providing a window to facilitate observation of sapphire crystal growth in a sapphire crystal growth furnace; and
providing a purging facility for reducing deposits on the sapphire growth window during sapphire crystal growth.

15. The method of claim 14, wherein the purging facility flows a gas in proximity to an interior side of the window to diminish a flow of out-gassed particles toward the window.

16. The method of claim 15, wherein the gas is an inert gas.

17. The method of claim 16, wherein the gas is argon gas.

18. The method of claim 15, wherein the flow of gas creates a pressure curtain in proximity to the window.

19. The method of claim 14, further comprising providing a facility for detecting discoloration of the window.

20. The method of claim 19, wherein the discoloration detection facility includes a sensor for detecting at least one of an apparent color change of a target item in the furnace, an amount of deposition on the window, and state of cleanliness of the window.

21. The method of claim 14, wherein the sapphire crystal growth furnace is used in a c-axis sapphire crystal growth process.

22. The method of claim 21, wherein the process is a controlled heat extraction process.

23. A method for growing a sapphire crystal, comprising:
providing a probe for use in detecting the status of growth of a seed crystal in a sapphire crystal growth furnace; and
deploying the probe in a sapphire crystal growth furnace to determine the size of a seed crystal.

24. The method of claim 23, wherein the probe is made at least in part of tungsten.

25. The method of claim 23, wherein the probe is disposed with a plurality of magnets to facilitate movement of the probe within the furnace.

26. The method of claim 23, wherein upon contact with the seed crystal, the probe stops moving relative to the movement of at least one moving magnet.

27. The method of claim 23, further comprising a measuring facility for measuring the height of the seed crystal based on the position of the probe.

28. The method of claim 23, wherein the sapphire crystal growth furnace is used in a c-axis sapphire crystal growth process.

29. The method of claim 28, wherein the process is a controlled heat extraction process.

30. The method of claim 23, further comprising automating a sapphire crystal growth process based on readings from the mechanical probe.

31. The method of claim 30, wherein the sapphire crystal growth furnace is used in a c-axis sapphire crystal growth process.

32. A method for growing a sapphire crystal, comprising:
providing a crucible for containing source material for sapphire crystal growth;
providing a cooling shaft for cooling at least a zone of the crucible; and
providing an intermediate facility for separating the crucible from the cooling shaft.

33. The method of claim 32, wherein at least one of the crucible and the cooling shaft is made at least in part of tungsten material.

34. The method of claim 32, wherein the intermediate facility is made of a material other than the composition of crucible or cooling shaft.

35. The method of claim 34, wherein the intermediate facility is made of a heat-resistant alloy.

36. The method of claim 35, wherein the alloy is molybdenum, tungsten, or a mixture of molybdenum, tungsten, rhenium or other high temperature alloys.

37. The method of claim 32, wherein the sapphire crystal growth crucible is used for c-axis sapphire crystal growth.

38. The method of claim 37, wherein the process is a controlled heat extraction process.

39. The method of claim 32, wherein the intermediate facility is a refractory metal disc.

40. The method of claim 32, wherein the intermediate facility is molybdenum or tungsten.

41. The method of claim 32, wherein the intermediate facility is coated.

42. The method of claim 41, wherein the coating is a refractory oxide.

43. The method of claim 42, wherein the refractory oxide is selected from the group consisting of yttria, alumina, zirconia, and yttria stabilized zirconia.

44. A method for growing a sapphire crystal, comprising:
providing a crucible for sapphire crystal growth; and
shaping the crucible in a non-circular shape, thereby facilitating growth of a crystal to a non-circular shape.

45. The method of claim 44, wherein the crucible is used in a c-axis sapphire crystal growth process.

46. The method of claim 45, wherein the process is a controlled heat extraction process.

47. The method of claim 44, wherein the crucible is formed by pressing and sintering, followed by machining to non-circular dimensions.

48. The method of claim 44, further comprising positioning a seed crystal to facilitate a-axis growth that is orthogonal to a flat side of the crucible.

49. The method of claim 44, wherein the crucible is used in a a-axis or m-axis crystal growth process.

50. The method of claim 44, further positioning a seed crystal to identify c-axis in the grown crystal that is orthogonal to the growth axis of the crystal.
